(19) United States
(12) Patent Application Publication
(10) Pub. No.: US 2019/0074578 A1
(43) Pub. Date: Mar. 7, 2019

(54) Piezoelectric Transmitter

(71) Applicant: The Board of Trustees of the Leland Stanford Junior University, Palo Alto, CA (US)

(72) Inventors: Matthew A. Franzi, Burlingame, CA (US); Erik N. Jongewaard, Sunnyvale, CA (US); Mark A. Kemp, Belmont, CA (US); Emilio A. Nanni, Stanford, CA (US)

(21) Appl. No.: 16/121,158

(22) Filed: Sep. 4, 2018

Related U.S. Application Data
(60) Provisional application No. 62/554,417, filed on Sep. 5, 2017.

(51) Int. Cl. H01Q 1/38; H01Q 13/24; H04R 17/00; H03H 9/25

(52) U.S. Cl. CPC H01Q 1/38; H03H 9/25; H04R 17/005; H01Q 13/24

(57) ABSTRACT

A piezoelectric dipole transmitter is provided that includes a piezoelectric element comprising a mechanical resonance frequency, an insulating support disposed at a midpoint of the piezoelectric element, an external capacitance actuator driver, and an external capacitance actuator disposed proximal to one end of the piezoelectric element, where the capacitance actuator is driven by the external capacitance actuator driver to output a capacitive drive signal excites a length-extensional acoustic mode of the piezoelectric element to resonate at a piezoelectric element resonance frequency, where the piezoelectric element radiates energy as an electric dipole.

### CROSS-REFERENCE TO RELATED APPLICATIONS

This application claims priority from U.S. Provisional Patent Application 62/554,417 filed Sep. 5, 2017, which is incorporated herein by reference.

### STATEMENT OF GOVERNMENT SPONSORED SUPPORT

This invention was made with Government support under contract DE-AC02-76SF00515 awarded by the Department of Energy. The Government has certain rights in the invention.

### FIELD OF THE INVENTION

The present invention relates generally to antenna transmitters. More particularly, the invention relates to a dipole piezoelectric transmitter.

### BACKGROUND OF THE INVENTION

Traditional metallic antennas much shorter than the radiating wavelength require large charge separation (dipole moments) and have huge input impedances, impractical for efficient and compact operation. To generate the large currents necessary to overcome their fundamentally low radiation efficiency, very high input voltages and impedance-matching networks are typically required. Next-generation antennas based upon the mechanical manipulation of charges bypass many challenges of electrically small antennas, particularly in the Very Low Frequency (VLF, 3-30 kHz) band. If successful, these will enable transmitters with a size and power consumption compatible with man-portable applications capable of closing communication links at distances greater than 100 km.

### BRIEF DESCRIPTION OF THE DRAWINGS

FIG. 1 shows a sketch of the VAPOR transmitter. The device is axisymmetric about the center of the figure, according to one embodiment of the invention.

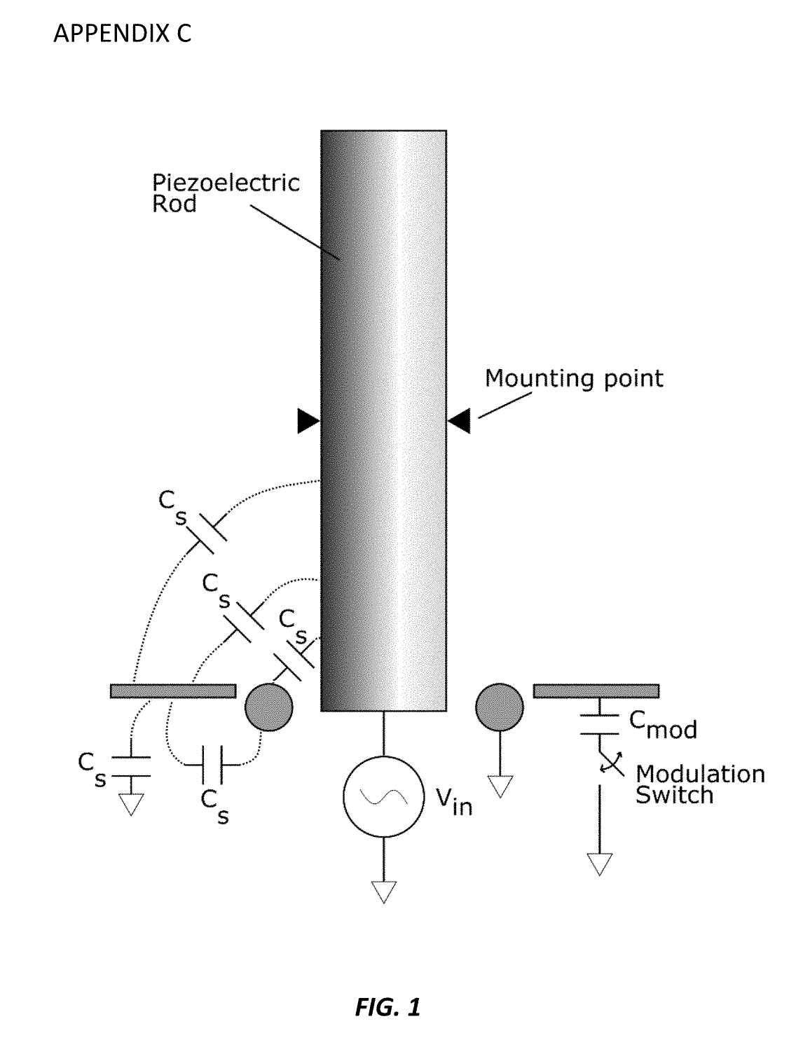

FIG. 2 shows multiphysics simulation of VAPOR. Shading represents mechanical displacement magnitude. Dark shading is little movement while light shading is high displacement. The arrows are the electric displacement vectors within the piezoelectric crystal, according to one embodiment of the invention.

FIG. 3 shows a circuit schematic of VAPOR. Included are the input generator, the equivalent circuit for the piezoelectric resonator operating with one mode, the radiated field, and the modulation capacitance, according to one embodiment of the invention.

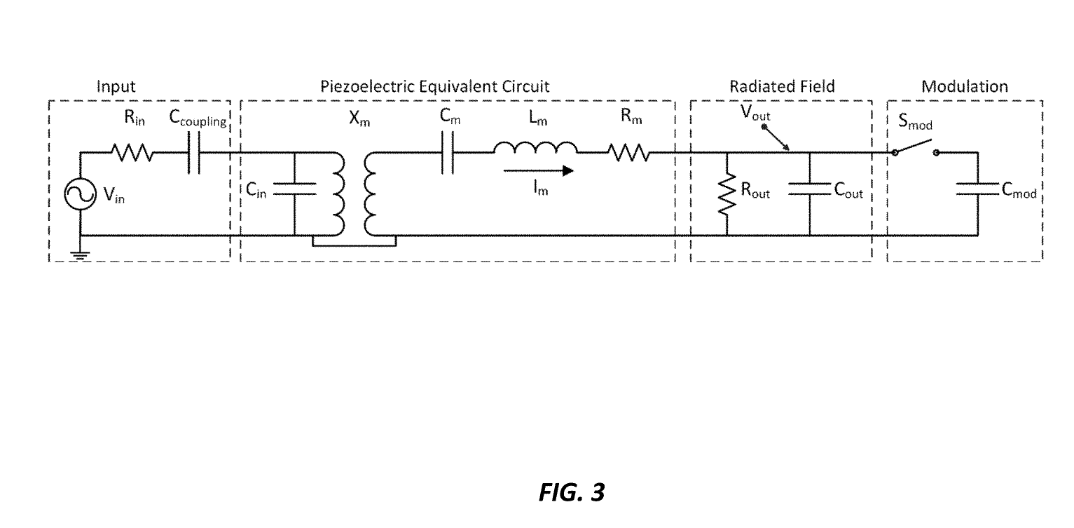

FIG. 4 shows radiated field at two different values of external capacitance. The bandwidth of each individual curve is dictated by the Q of the crystal. Without DAM, one would operate between points “a” and “b” on curve 1. DAM allows operation between bother curves, at the point of highest field, “a” and “c.”, according to one embodiment of the invention.

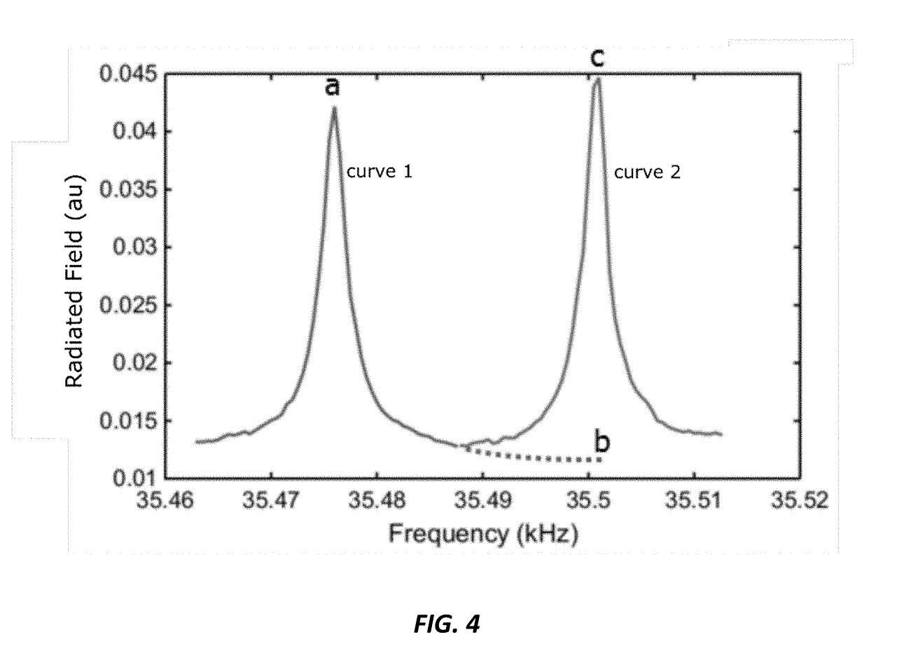

FIGS. 5A-5B show the effect of DAM on radiated field. (top) spectrogram of input crystal current to the crystal with 500 ms FFT window. (bottom) lineout of the two tones of interest. 250 ms window FFT with 200 ms overlap for each point, according to one embodiment of the invention.

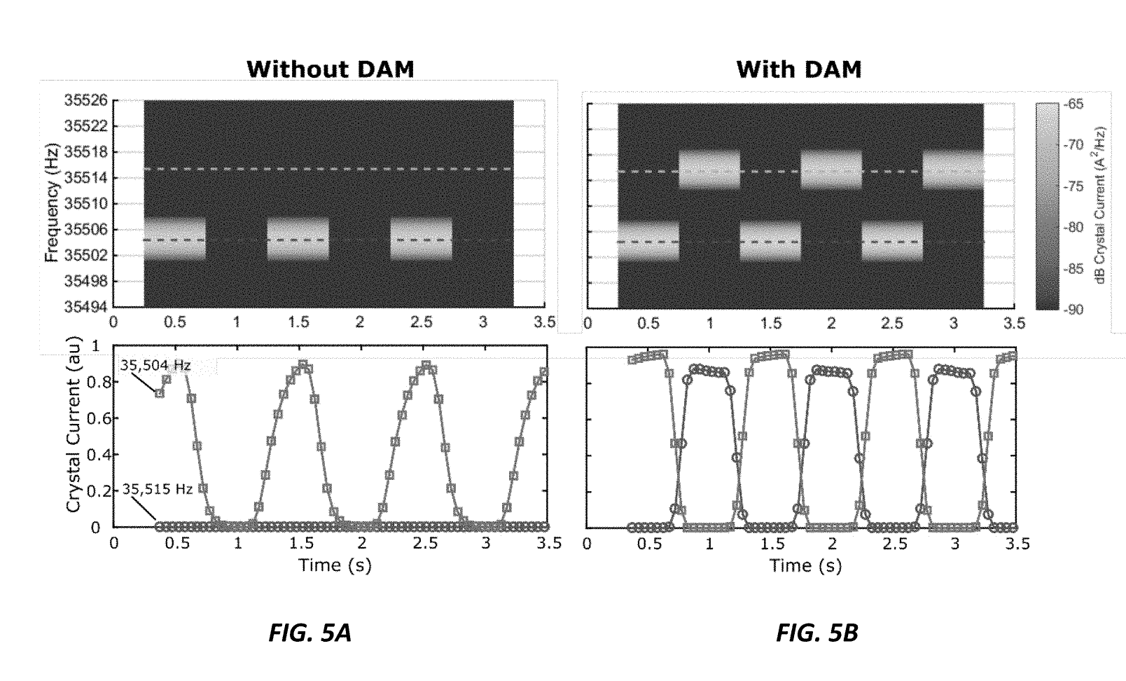

### DETAILED DESCRIPTION

Traditional metallic antennas much shorter than the radiating wavelength require large charge separation (dipole moments) and have huge input impedances, impractical for efficient and compact operation. To generate the large currents necessary to overcome their fundamentally low radiation efficiency, very high input voltages and impedance-matching networks are typically required. Next-generation antennas based upon the mechanical manipulation of charges bypass many challenges of electrically small antennas, particularly in the Very Low Frequency (VLF, 3-30 kHz) band. If successful, these will enable transmitters with a size and power consumption compatible with man-portable applications capable of closing communication links at distances greater than 100 km.

The current invention provides vibrating piezoelectric elements to generate a large dipole moment and subsequently radiate VLF signals. Piezoelectric materials generate a displacement current in response to an applied time-varying stress. Operating near mechanical resonance, modest input excitation can generate large displacement currents. A piezoelectric resonator can radiate fields in a compact form factor by rendering unnecessary the large and inefficient electrical components required in traditional antennas. In effect, the piezoelectric device is simultaneously a high-current generator, high-Q matching network, and radiating antenna.

In one embodiment, the SLAC VLF Antenna PiezOelectric Resonator (VAPOR) concept utilizes a suitable piezoelectric material, such as for example Lithium Niobate (LN), as a length-extensional piezoelectric transformer. Radiation efficiency is maximized through mitigating the loss mechanisms of the material and the mechanical assembly. The resonator resonant frequency is dynamically tuned to achieve frequency modulation in a high-Q resonator.

Demonstrating efficient, portable VLF transmitters requires technological advances in both the conceptual implementation and materials performance of piezoelectric resonators. The primary metric of success for the VAPOR program is to maximize the electric dipole moment while minimizing the dissipated power. Size and weight are set to achieve a compact and transportable system. The primary innovations are 1) demonstrating a LN resonator with a Qm>100,000, 2) modulating the resonator at 500 Hz/sec, and 3) demonstrating robust controls to transform the resonator into a communication system. Ultra-Low Frequency and Very Low Frequency (VLF) communication systems (0.3-3 kHz and 3 kHz-50 kHz, respectively) have been used for many decades for a broad range of applications. These long-wavelength bands have applications not possible at higher frequencies. This is due to a few advantageous characteristics. While coupling to the earth-ionosphere waveguide, VLF signals have path attenuation less than 3 dB/1000 km (cite). In addition, because the skin effect in materials is inversely proportional to frequency, VLF signals can penetrate 10's of meters into seawater or the earth, while higher frequency signals quickly are attenuated. For example, underwater communication with submarines is presently accomplished through large VLF transmitters located at many locations around the world.

Efficient VLF transmitters have traditionally necessitated radiating elements at the scale of the wavelength: several kilometers. This is because the radiation resistance, R_{rad}, of an electric dipole which scales as (L/λ₀)² where L is the electrical length of the antenna and λ₀ is the free space wavelength of the transmitting frequency. The radiation efficiency scales as R_{rad}/Rₜₒₜₐₗ where Rₜₒₜₐₗ is the total resistance of the antenna system including effects such as copper losses. Therefore, as the physical size of the antenna decreases, unless antenna losses are proportionally reduced, the efficiency dramatically reduces. This effect is exacerbated in the case of magnetic dipoles as the radiation resistance scales as (L/λ₀)⁴.

These characteristics have previously limited the applicability of VLF communication systems, particularly for portable transmitters. We introduce a transmitter, the VLF Antenna Piezoelectric Resonator (VAPOR) which aims to break this barrier. This is enabled by three novel aspects. First, we excite a length-extensional acoustic mode of a piezoelectric device such that it resonates at VLF and radiates energy as an electric dipole. The use of a piezoelectric element as a radiator eliminates the need for large impedance matching elements. Second, we utilize an extremely high-Q single crystal (>45,000) to minimize antenna losses. While the radiation resistance is still low, we dramatically reduce the losses within the transmitter, and thereby increase the efficiency several orders of magnitude over what is presently achievable. Third, we use a novel technique of direct antenna modulation (DAM) to dynamically shift the resonant frequency of the crystal. This technique allows us to bypass the Bode-Fano limit for high-bandwidth communications.

According to one embodiment, the invention provides a man-portable form-factor: <5 W power consumption, <9.4 cm long, <1 kg. Consider an electric dipole of a 9.4 cm-long wire normal to a ground plane. The input impedance of this antenna is ˜2 pF, or −j2.3 M [symbol] at 35 kHz. The required 10.5 H impedance matching inductance has practical limitations. First, the number of windings and core size both lead to large volume and mass. Second, the winding copper losses greatly reduce the radiation efficiency. Third, a useable field generated from the antenna necessitates a high energization. For example, to generate a 5 mA-m dipole moment, 125 kV is needed to drive the antenna. A 125 kV, 10.5 H inductor is many times larger than the antenna itself and would have substantial deleterious parasitic elements (eg, winding capacitance).

The potential utility of piezoelectric materials within radiating elements has been recognized for many years. Radiation has been measured from vibrating quartz resonators and much of the analytical development has been demonstrated. Similarly, piezo-magnetic or multiferroic antennas have also been proposed as enabling techniques for electrically-small transmitters. An advantage of strain-based antennas is that they resonate at an acoustic frequency with physical dimensions much less than the electromagnetic wavelength. If effect, there is no need for large, external impedance-matching elements.

Having no matching network greatly improves portability. However, if a low-Q antenna also has high radiation Q, then the radiation efficiency can be prohibitively low. Common piezoelectric devices typically have Qs from around 50 up to around 2,000 (cite). This Q is primarily determined by mechanical losses in the system (cite). VAPOR utilizes a single crystal lithium niobate piezoelectric radiating element with a mechanical Q of greater than 50,000. In doing so, we improve the radiation efficiency of the system by >12×.

High Q communication systems are typically low bandwidth, which results in low bitrates. Typically, as high of a bitrate is possible is desirable. The general constraining relationships are the Chu limit and the Bode-Fano limits. Generically, these limits state that the achievable bandwidth scales as f_{c}/Q where f_{c} is the carrier frequency. With a carrier frequency of 35 kHz and a Q of 45,000, the achievable bandwidth would be ˜0.75 Hz. A parametric modulation scheme, Direct Antenna Modulation (DAM), can bypass these limits. Simply, we dynamically shift the resonant frequency to widen the effective bandwidth.

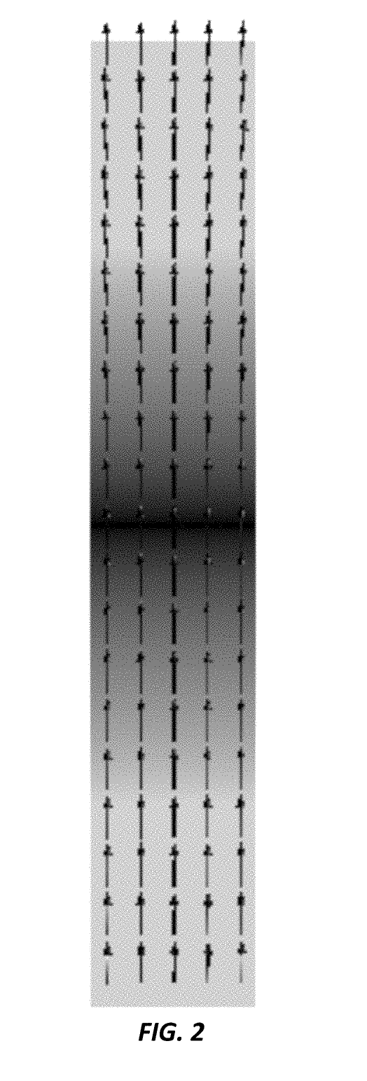

This can be physically realized by several mechanisms. VAPOR uses an external time-varying capacitance to modulate the resonant frequency. As shown in FIG. 2, an electrically floating conductive plate capacitively couples to the piezoelectric device as well as ground. This is illustrated by various stray capacitances, Cₛ. One side of a fixed capacitance is connected to this floating plate, and the other end connects to one side of an electrical relay. The relay shorts and opens this capacitance to ground coincident with the change in the drive RF frequency. The two drive frequencies are chosen such that they match the resonant circuit with either the relay switch open or closed.

Further details, variations and embodiments are described in the attached APPENDICIES, which are hereby incorporated to this provisional application.
APPENDIX A is a document describing the invention titled “VLF Antenna PiezOelectric Resonator (VAPOR)” (13-pages).
APPENDIX B is a slide presentation describing the invention titled “VLF Antenna PiezOelectric Resonator (VAPOR)” (15-slides).
APPENDIX C is a document showing figures describing the invention (5-sheets).
APPENDIX D is a document describing the invention titled “Demonstration of a Parametric Modulation Scheme” (8-pages).

What is claimed:

1) A piezoelectric dipole transmitter, comprising:
a) a piezoelectric element comprising a mechanical resonance frequency;
b) an insulating support disposed at a midpoint of said piezoelectric element;
c) an external capacitance actuator driver; and
d) an external capacitance actuator disposed proximal to one end of said piezoelectric element, wherein said capacitance actuator is driven by said external capacitance actuator driver to output a capacitive drive signal excites a length-extensional acoustic mode of said piezoelectric element to resonate at a piezoelectric element renonance frequency, wherein said piezoelectric element radiates energy as an electric dipole.

2) The piezoelectric dipole transmitter of claim 1, wherein said piezoelectric element comprises a cylindrical piezoelectric rod, a cuboid rod, or a shape that resonates in said length-extension mode.

3) The piezoelectric dipole transmitter of claim 1, wherein said external capacitance actuator comprise a plurality of concentric capacitor rings, or an external conductor having a controllable capacitance-to-ground that are disposed proximal to one end of said piezoelectric element.

4) The piezoelectric dipole transmitter of claim 1, wherein said piezoelectric radiating element has an output signal voltage in a range of at least 100V.

5) The piezoelectric dipole transmitter of claim 1, wherein said piezoelectric element comprises a material selected from the group consisting of lithium niobate, quartz, and lithium tantalate.

6) The piezoelectric dipole transmitter of claim 1, wherein said modulation capacitance charges and discharges at a frequency in a range of 1 Hz-1 kHz.

7) A piezoelectric dipole transmitter, comprising:
a) a piezoelectric element;
b) a piezoelectric actuator attached to one end of said piezoelectric element;
c) a capacitive plate, wherein said capacitive plate is proximal to said piezoelectric crystal and said piezoelectric actuator;
d) a piezoelectric actuator driver, wherein said piezoelectric actuator driver has an output drive signal voltage in a range of 10V-1 kV, and a frequency of 1 kHz-1 MHz; and
e) a capacitive plate driver, wherein said capacitive plate driver charges and discharges said capacitive plate at a frequency in a range of 1 Hz-1 kHz.

8) The piezoelectric dipole transmitter of claim 7, wherein said piezoelectric element comprises a material selected from the group consisting of lithium niobate, quartz, and lithium tantalate.

9) The piezoelectric dipole transmitter of claim 7 further comprising a mechanically-free mass load on one end of said piezoelectric crystal.

10) The piezoelectric dipole transmitter of claim 7, wherein said external capacitance actuator driver has an output drive signal voltage in a range of 100V-80 kV, and a frequency of 1 kHz-1 MHz.
